(19) United States
(12) Patent Application Publication
(10) Pub. No.: US 2007/0217276 A1
(43) Pub. Date: Sep. 20, 2007

(54) FUSE LATCH CIRCUIT, SEMICONDUCTOR DEVICE AND SEMICONDUCTOR MEMORY SYSTEM

(75) Inventor: Yoshinori Sugisawa, Kanagawa (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/687,084

(22) Filed: Mar. 16, 2007

(30) Foreign Application Priority Data
Mar. 17, 2006 (JP) 2006-074961

(51) Int. Cl. G11C 17/18; G11C 29/00; G11C 17/00; G11C 7/00

(52) U.S. Cl. 365/225.7; 365/200; 365/96

(57) ABSTRACT

A data storing fuse element unit includes a plurality of fuse elements, stores data in the respective fuse elements in a bit unit in accordance with presence and absence of cutting of fuse elements, and a latch circuit unit latches the stored data by the bit unit. A logic information storing fuse element unit stores logic information of whether output logic of the data stored in the fuse elements is to be inverted or not. A data selecting unit selects any one of data latched in the latch circuit unit and data with the output logic of the data latched in the latch circuit unit inverted in a logic inverting unit, in accordance with logic information of the logic information storing fuse element unit and outputs the data.

### CROSS-REFERENCE TO RELATED APPLICATIONS

This application is based upon and claims the benefit of priority from the prior Japanese Patent Application No. 2006-074961 filed on Mar. 17, 2006; the entire contents of which are incorporated herein by reference.

### BACKGROUND OF THE INVENTION

1. Field of the Invention

The present invention relates to a fuse latch circuit that includes a plurality of fuse elements, and decreases the number of fuse elements which are cut when storing data in a bit unit into the respective fuse elements in accordance with presence and absence of cutting of the plurality of fuse elements to enhance throughput and yield of a fuse element cutting process step, a semiconductor device and a semiconductor memory system.

2. Description of Related Art

In a semiconductor memory device (memory chip) such as a DRAM (Dynamic Random Access Memory) and an SRAM (Static Random Access Memory), a redundancy circuit method which replaces a defect with a memory cell in a redundancy memory cell array when the fault (defect) is detected in a memory cell in a memory cell array, and enhances the yield of the products is adopted.

In the redundancy circuit method generally used at present, a plurality of word lines or a single word line, or a plurality of bit lines or a single bit line is the unit for relief (namely, a relief unit) in a sub block of memory cells. The relief unit including the memory cell having a defect in the sub block is replaced with the redundancy unit of the same size as the relief unit in the redundancy memory cell array.

For storage of the address information of the relief unit having a defect, a nonvolatile memory element has to be used, and a fuse latch circuit is generally used at present. The address information is usually configured by a plurality of bits, and therefore, the fuse set including a plurality of fuse elements corresponding to this is the unit of redundancy. Data of a 1 and 0 logical value of a plurality of bits stored in accordance with cut and uncut state of a plurality of fuse elements is outputted from the fuse latch circuit.

Normally, the relief unit and the fuse set are brought into one to one correspondence with each other, and the same number of fuse sets as the number of relief units are provided in the chip. When redundancy relief of a defective memory cell is performed, the fuse elements in the corresponding fuse set are cut in accordance with the bit content of the specified address information. An address decoder compares the address of the defective memory cell stored in the fuse latch circuit and the input address, and when they coincide with each other, the address decoder selects the redundancy memory cell to be replaced in the redundancy memory cell array. The method is simple in configuration, and is widely adopted at present.

In the fuse element cutting process step, cutting of wiring is performed by irradiating a laser beam into the chip from outside. In the following explanation, the case where the fuse elements are cut by irradiating a laser beam will be described as fuse element cutting.

Conventionally, the fuse latch circuit which latches the defect relief information (for example, address information of a defective cell) of a semiconductor memory device having redundancy cells has the configuration in which a fuse element is connected to between a high potential (VDD) and a low potential (VSS), and output is taken out with the high potential (VDD) side as an output terminal, speaking of the circuit per 1 bit in the fuse latch circuit, that is, the circuit per one fuse element. With such a configuration, if the fuse element is not cut, VSS, namely, “0” (low level) is outputted, and if the fuse element is cut, VDD, namely, “1” (high level) is outputted.

Namely, in the fuse latch circuit, the outputted data direction (“1”, “0”) is determined depending on whether the fuse element is cut by laser or not, and it is general that in the above described configuration, “0” (low level) is outputted with non-cut (conductive state), and “1” (high level) is outputted with cut. In this case, the number of fuse elements which are cut depends on the relief information of a defect, that is, the address information of a defective cell, and when a large number of “1” exist in the information, the number of fuse elements which are cut increases, and the through put and yield of the step are adversely affected. Namely, when the number of fuse elements which are cut increases, the problems of requiring time for the fuse element cutting process step, reducing the throughput of the process step, and causing reduction in yield based on cutting failure (failure in cutting) are caused.

As the conventional art, there is proposed a semiconductor memory device which intends reduction in erroneous output due to noise or the like, by making the data to be latched dual by giving bit data of two logical values of positive and negative that are the non-inverted and the inverted logical value of the output as the means which makes it difficult to cause erroneous output due to a noise or the like is proposed in a fuse latch circuit (for example, see Japanese Patent Laid-open No. 2002-288992).

Japanese Patent Laid-open No. 2002-288992 is one of a kind of means that enhances yield, however, it does not reduce the number of fuse elements which are cut in the fuse element cutting process step as described above.

### BRIEF SUMMARY OF THE INVENTION

According to one aspect of the invention of the present application, there is provided a fuse latch circuit including a data storing fuse element unit configured to include a plurality of fuse elements, and store data in the respective fuse elements in a bit unit in accordance with presence and absence of cutting of the plurality of fuse elements, a latch circuit unit configured to include an equivalent number of latch circuits to the plurality of fuse elements of the data storing fuse element unit, and latch the data stored in the data storing fuse element unit in a bit unit, a logic information storing fuse element unit configured to store logic information of whether output logic of data stored in the fuse element is to be inverted or not in accordance with presence and absence of cutting of a fuse element, a logic inverting unit configured to input therein the data latched in a bit unit into the plurality of the latch circuits configuring the latch circuit unit, and invert output logic of the data to output the data serially, and a data selecting unit configured to select any one of data that is serially outputted with the output logic of the data latched in the latch circuit unit unchanged, and data that is serially outputted with the output logic of the data latched in the latch circuit unit inverted in the logic inverting unit, in accordance with logic information stored in the logic information storing fuse element unit to output the data serially.

According to another aspect of the invention of the present application, there is provided a fuse latch circuit including a data storing fuse element unit configured to include a plurality of fuse elements, and store data in the respective fuse elements in a bit unit in accordance with presence and absence of cutting of the plurality of fuse elements, a logic information storing fuse element unit configured to store logic information of whether output logic of data stored in the fuse elements is to be inverted or not in accordance with presence and absence of cutting of a fuse element, a logic inverting unit configured to include an equivalent number of logic inverting circuits to the plurality of fuse elements configuring the data storing fuse element unit, and invert output logic of the data stored in the data storing fuse element unit in a bit unit to output the data in parallel, and a data selecting unit configured to include an equivalent number of data selecting circuits to the plurality of fuse elements of the data storing fuse element unit, and select any one of data that is outputted in parallel, with the output logic of the data stored in the data storing fuse element unit unchanged, and data that is outputted in parallel, with the output logic of the data stored in the data storing fuse element unit inverted in the logic inverting unit, in accordance with logic information stored in the logic information storing fuse element unit to output the data in parallel, and a latch circuit unit configured to include an equivalent number of latch circuits to the plurality of data selecting circuits configuring the data selecting unit, and latch data outputted from the data selecting unit in a bit unit to output the data in parallel and/or serially.

According to another aspect of the invention of the present application, there is provided a semiconductor memory system including a fuse latch circuit comprising a data storing fuse element unit configured to include a plurality of fuse elements, and store data in the respective fuse elements in a bit unit in accordance with presence and absence of cutting of the plurality of fuse elements, a latch circuit unit configured to include an equivalent number of latch circuits to the plurality of fuse elements of the data storing fuse element unit, and latch the data stored in the data storing fuse element unit in a bit unit, a logic information storing fuse element unit configured to store logic information of whether output logic of data stored in the fuse element is to be inverted or not in accordance with presence and absence of cutting of a fuse element, a logic inverting unit configured to input therein the data latched in a bit unit into the plurality of the latch circuits configuring the latch circuit unit, and invert output logic of the data to output the data serially, and a data selecting unit configured to select any one of data that is serially outputted with the output logic of the data latched in the latch circuit unit unchanged, and data that is serially outputted with the output logic of the data latched in the latch circuit unit inverted in the logic inverting unit, in accordance with logic information stored in the logic information storing fuse element unit, and serially output the data, wherein the data storing fuse element unit stores data of an address of a defective cell of a cell array of a memory chip as a semiconductor device in a bit unit, and a fuse cutting device configured to carry out the cutting of fuse elements in the fuse latch circuit, the fuse cutting device configured to invert all bit data of the address, generate “1” as a logic information adding bit of the logic information storing fuse element unit, and perform cutting/non-cutting processing of the plurality of fuse elements of the data storing fuse element unit and the fuse element of the logic information storing fuse element unit (cut in the case of “1”, non-cut in the case of “0”) when a number of “1”s is larger as compared with a number of “0”s in all the bit data configuring the address of a defective cell obtained as a result of a test of the memory chip by a memory tester, the fuse cutting device configured to leave all the bit data of the address unchanged (non-inversion), generate “0” as the logic information adding bit of the logic information storing fuse element unit, and perform cutting/non-cutting processing of the plurality of fuse elements of the data storing fuse element unit and the fuse element of the logic information storing fuse element unit when the number of “1”s is smaller as compared with the number of “0”s in all the bit data configuring the address of the defective cell, and the fuse cutting device configured not to invert all the bit data of the address stored in the data storing fuse element unit, generate “0” as the logic information adding bit of the logic information storing fuse element unit, and perform cutting/non-cutting processing of the plurality of fuse elements of the data storing fuse element unit and the fuse element of the logic information storing fuse element unit when the number of “1”s and the number of “0”s are the same in all the bit data configuring the address of the defective cell.

### BRIEF DESCRIPTION OF THE DRAWINGS

FIG. 1 is a circuit diagram showing a fuse latch circuit of a first embodiment of the present invention;

FIG. 2 is a block diagram showing the configuration of a semiconductor device according to the present invention;

FIG. 3 is a circuit diagram showing a fuse latch circuit of a second embodiment of the present invention; and

FIG. 4 is a circuit diagram showing a fuse latch circuit of a third embodiment of the present invention.

### DETAILED DESCRIPTION OF THE INVENTION

An embodiment of the present invention will be described with reference to the drawings.

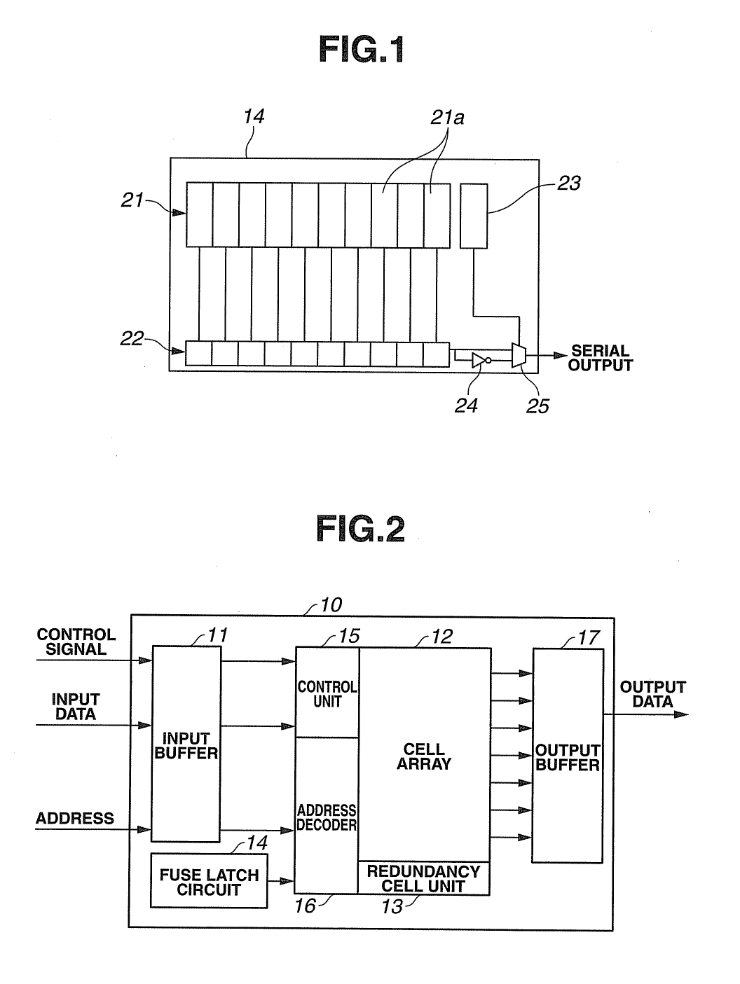

Before describing a fuse latch circuit of the present invention with FIG. 1, a semiconductor device in which the fuse latch circuit of the present invention is used will be described with reference to FIG. 2.

FIG. 2 is a block diagram showing the semiconductor device in which the fuse latch circuit according to the present invention is used. Here, a DRAM as the semiconductor device will be described.

As shown in FIG. 2, a memory chip 10 as the semiconductor device includes an input buffer 11, a cell array 12, a redundancy cell unit 13, a fuse latch circuit 14, a control unit 15, an address decoder 16 and an output buffer 17.

A control signal, data and an address are supplied to the above described input buffer 11 as input. The cell array 12 includes a plurality of memory cells arranged in a matrix form.

The above described redundancy cell unit 13 has redundancy cells to be replaced with defective cells in the cell array 12. The redundancy cells are assigned with addresses different from those of the memory cells in the cell array 12.

The above described fuse latch circuit 14 stores the addresses of the defective cells corresponding to presence and absence of fuse element cutting and outputs them. The control unit 15 controls reading and writing data from and in the cell array 12 by using a control signal which is inputted therein.

The above described address decoder 16 compares an input address and the address of a defective cell from the fuse latch circuit 14. When they coincide with each other, the address decoder 16 drives the redundancy cell with the address determined in advance in the redundancy cell unit 13 to correspond to the input address, and when they do not coincide with each other, the address decoder drives the memory cell in the cell array 12 corresponding to the input address. The output buffer 17 inputs therein data read from the cell array 12, and outputs it as output data. The output buffer 17 inputs therein a parallel signal read from the cell array 12, for example, and outputs a serial signal as output data.

In order to detect a defective cell included in the cell array 12, for example, a memory tester not shown is used, test data is successively supplied into the memory cells in sequence of address as input, a defective cell is found by comparing the inputted test data and the data read out from the memory cells as output, and the address of the defective cell can be acquired.

When data is written into the cell array 12 in the above described configuration, the input data, the address and a write control signal which instructs write are supplied to the input buffer 11 and held temporarily. Thereafter, the write control signal is supplied to the control unit 15, the address is supplied to the address decoder 16, and the input data is supplied to the cell array 12, respectively. The control unit 15 performs a control of writing the input data into the cell array 12 in accordance with the address obtained by decoding the supplied address in the address decoder 16, based on the write control signal.

Meanwhile, when the data of the cell array 12 is read, the address and the read control signal which instructs read are supplied to the input buffer 11 and held temporarily. Thereafter, the read control signal is supplied to the control unit 15, and the address is supplied to the address decoder 16, respectively. The control unit 15 performs a control of reading the data written in the cell array 12 from the cell array 12 in accordance with the address decoded in the address decoder 16, based on the read control signal.

As described above, in order to have an access to the memory cell in the cell array 12 or the redundancy cell in the redundancy cell unit 13 on the occasion of write to and read the cell array 12, the address decoder 16 first compares the input address with the addresses of the defective cells stored in the fuse latch circuit 14. When the address coincides with the address of one of the defective cells, the address decoder 16 selects and drives the redundancy cell in the redundancy cell unit 13, and when the address does not coincide with any of the addresses, the address decoder 16 can drive the memory cell in the cell array 12 corresponding to the input address.

### First Embodiment

FIG. 1 is a circuit diagram showing a fuse latch circuit of a first embodiment of the present invention.

As shown in FIG. 1, the fuse latch circuit 14 includes a data storing fuse element unit 21, a latch circuit unit 22, a logic information storing fuse element unit 23, a logic inverting unit 24, and a data selecting unit 25.

The above described data storing fuse element unit 21 includes a plurality (ten in the drawing) of fuse elements 21a, and stores data (for example, address information of defective cells) in the respective fuse elements by a bit unit in accordance with the presence and absence of cutting of the fuse elements. The information stored in the plurality of fuse elements 21a of the data storing fuse element unit 21 in a bit unit is electrically readable. More specifically, speaking of the circuit by one bit, that is, the circuit per one fuse element as described in the prior art, a fuse element is connected between a high potential (VDD) and a low potential (VSS), and the output in a bit unit can be taken out with the high potential (VDD) side as the output terminal. The address information of the defective cell stored by cutting of the fuse elements will be described later. As the metal material of the fuse element, the same conductive material as generally used in wiring is used, and for example, aluminum (Al), copper (Cu), polysilicon and the like are used.

The above described latch circuit unit 22 includes the equivalent number (ten in the drawing) of latch circuits to the plurality of fuse elements 21a of the above described data storing fuse element unit 21, and latches the data outputted from the fuse elements 21a of the data storing fuse element unit 21 in a bit unit and serially outputs them. Each of the latch circuits configuring the latch circuit unit 22 is configured by a flip-flop. The data storing fuse element unit 21 outputs the stored information of the plurality of fuse elements 21a in parallel by the bit unit, and the latch circuit unit 22 configures a shift register including a plurality of latch circuits (flip-flops) holding a plurality of data in a bit unit which are outputted in parallel. The latch circuit unit 22 as the shift register serially outputs the parallel input data synchronously with a clock signal.

The above described logic information storing fuse element unit 23 includes one fuse element, and stores the logic information of whether the output logic of the data stored in the fuse element 21a of the above described data storing fuse element unit 21 is inverted or not (inversion “1”, non-inversion “0”) in one bit, by presence or absence of cutting of the fuse element. The logic inverting unit 24 inverts the output logic of a bit string configuring the data outputted from the latch circuit unit 22 and serially outputs the data.

The above described data selecting unit 25 selects any one of the serial data with the output logic of the data outputted from the latch circuit unit 22 unchanged, and the serial data with the output logic of the data outputted from the latch circuit unit 22 inverted in the logic inverting unit 24, in accordance with the logic information of one bit (“1” or “0”) of the logic information storing fuse element unit 23, and serially outputs the data to the address decoder 16 (see FIG. 2) as the address of a defective cell. Namely, if the logic information is “1”, the data inverted in the logic inverting unit 24 is selected and is outputted to the address decoder 16 as the address of the defective cell. If the logic information is “0”, the data passing by the logic inverting unit 24 is selected and is outputted to the address decoder 16 as the address of the defective cell.

With respect to which fuse elements are to be cut or uncut of the ten fuse elements 21a of the data storing fuse element unit 21 shown in FIG. 1, when the address of a defective cell is configured by 10 bits, for example, if the address have a larger number of “1”s, the number of fuse elements to be cut is larger than the number of fuse elements not to be cut, since “0” means not to cut, and “1” means to cut.

Thus, in a fuse cutting device (not shown) which carries out cutting of fuse elements by laser, when the number of “1”s is larger than the number of “0”s in all the bit data configuring the address of the defective cell obtained as a result of the test of the memory chip 10 by the memory tester, all the bit data of the address are inverted, “1” is generated as a logic information adding bit, and cut/non-cut processing of the plurality of fuse elements of the data storing fuse element unit 21 and the fuse element of the logic information storing fuse element unit 23 is performed. “1” means to cut, and “0” means not to cut. When the number of “1”s is smaller as compared with the number of “0”s in all the bit data configuring the address of the defective cell which is obtained as a result of the test of the memory chip 10 by the memory tester, all the bit data of the address are left intact (non-inverted), “0” is generated as the logic information adding bit, and cutting/non-cutting processing of the plurality of fuse elements of the data storing fuse element unit 21 and the fuse element of the logic information storing fuse element unit 23 is performed. When the number of “1”s and the number of “0”s are the same in all the bit data configuring the address of the defective cell, all the bit data of the address is non-inverted, and “0” is generated as the logic information adding bit, whereby as compared with all the bit data of the address are inverted, the number of fuse elements which are cut is reduced by one corresponding to the logic information storing fuse element.

Explaining it more specifically, if all the bit data configuring the address of a defective cell is “1011110101”, for example, the number of “1”s is larger. Therefore, in the fuse cutting device, all the data is inverted to generate “0100001010”, while “1” is generated as the logic information adding bit, and cutting processing of fuse elements corresponding to three bits of the data storing fuse element unit 21, and cutting processing of the fuse element corresponding to one bit of the logic information storing fuse element unit 23 are executed. For example, when all the bit data configuring the address are “1”, all the bits are inverted to be made “0”, “1” is generated as the logic information adding bit, and only cutting processing of the fuse element corresponding to one bit of the logic information storing fuse element unit 23 is executed.

As described above, if the number of “1”s is larger as compared with the number of “0”s in all the bit data configuring the address of a defective cell, the number of“1”s is made smaller as compared with the number of “0”s by performing inversion processing, and the number of fuse elements which are cut in the fuse element cutting process step can be reduced.

In FIG. 1, the case where the number of fuses of the relief unit of the address information, that is, one fuse set is 10 is described, but the number of fuses in one fuse set differs depending on the capacity of the chip (the numbers of word lines, bit lines and the like). For example, speaking of the example of DRAM of 1 Mbit, the number of word lines and bit lines are 512 and 2048, respectively, that is, 512 of row addresses, and 2048 of column addresses. Here, in order to facilitate the explanation, the word line, that is, the row address will be described as a unit. For the 512 memory cells of the row address, for example, eight redundancy cells are prepared. Since the number of fuse elements required for expressing the row address of the defective cell with respect to the eight redundancy cells have to be enough to express 512 different addresses from the addresses 0 to 511 of the defective cell, nine fuses are required for one redundancy cell, namely, one fuse set since 512=2⁹. Accordingly, 72 fuse elements are required in the eight redundancy cells. Further, in the DRAM of 32 Mbits, the number of fuses is 32 times as large as in the case of 1 Mbit, and 2304 fuses are required.

Next, a circuit operation in FIG. 1 will be described.

By fuse element cutting/non-cutting processing by the above described fuse cutting device, the number of “1”s of cut of, for example, ten fuse elements is always stored to be a half or smaller as compared with the number of “0”s of non-cut in the data storing fuse element unit 21. Meanwhile, in the logic information storing fuse element unit 23, the logic information showing whether logic inversion processing is performed for a plurality of fuse elements in the data storing fuse element unit 21 or not (“1” or “0”) is stored in one fuse element.

When the fuse latch circuit 14 supplies the address of a defective cell to the address decoder 16 shown in FIG. 2 in such a state, the fuse latch circuit 14 latches the bit data stored in the ten fuse elements of the data storing fuse element unit 21 by applying logic inversion processing to them in advance into the ten latch circuits of the latch circuit unit 22 corresponding to them, and applies inversed logic inversion processing to them to output them to the address decoder 16 as the serial data of the correct address. On this occasion, when the logic information adding bit stored in the logic information storing fuse element unit 23 is “1”, the data selecting unit 25 is controlled to select inverted output from the logic inversion unit 24. Therefore, the output data of the latch circuit 22 is logically inverted, and the correct address data of the defective cell is corrected and is supplied to the address decoder 16, from the fuse latch circuit 14.

When the logic information adding bit stored in the logic information storing fuse element unit 23 is “0”, the data selecting unit 25 selects the output data of the latch circuit unit 22 which passes by the logic inversion unit 24. Therefore, from the fuse latch circuit 14, the output data of the latch circuit unit 22 is directly outputted, and is supplied to the address decoder 16 as the correct address of the defective cell.

Therefore, in the fuse latch circuit 14, by inverting and outputting the stored data stored in the plurality of fuse elements 21a of the data storing fuse element unit 21 only when the state of the logic information storing fuse element unit 23 is “1”, the stored date can be returned to the correct address data of the defective cell.

According to the first embodiment, the data storing fuse element unit 21, the latch circuit unit 22, the logic information storing fuse element unit 23, the logic inverting unit 24 and the data selecting unit 25 are included, the number of fuse elements which are cut can be made a half of the number of fuse elements mounted on a chip, or less, the number of actual fuse elements which are cut of the data storing fuse element unit 21 is reduced, and throughput and yield in the fuse element cutting process step can be enhanced.

### Second Embodiment

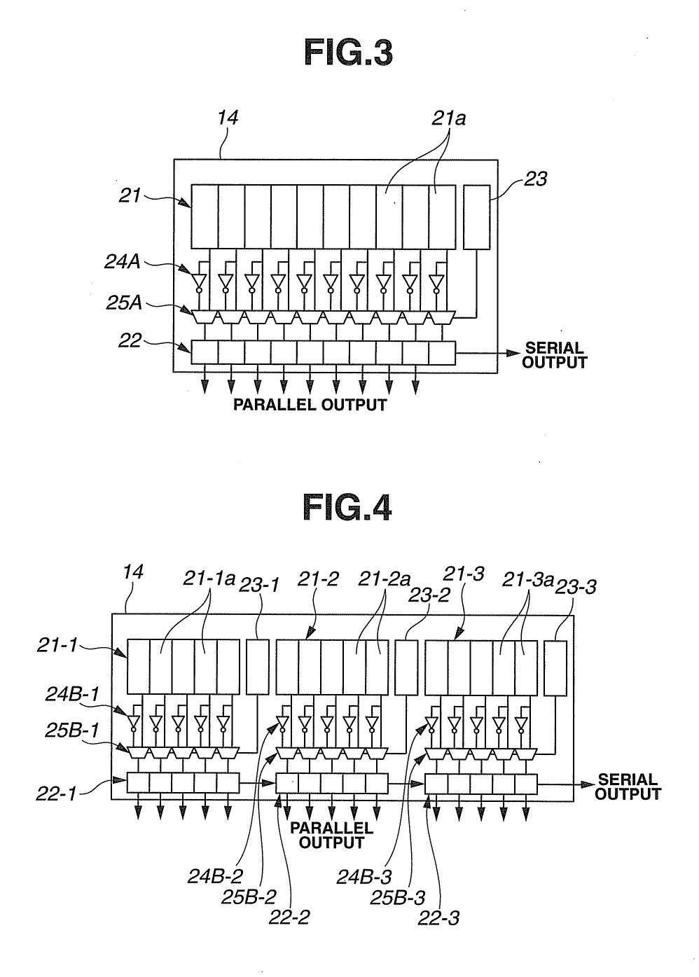

FIG. 3 is a circuit diagram showing a fuse latch circuit of a second embodiment.

As shown in FIG. 3, the fuse latch circuit 14 includes the data storing fuse element unit 21, the latch circuit unit 22, the logic information storing fuse element unit 23, a logic inverting unit 24A and a data selecting unit 25A.

The above described data storing fuse element unit 21 includes a plurality (10 in the drawing) of fuse elements 21a, and stores data (for example, address information of a defective cell) in the respective fuse elements in a bit unit in accordance with the presence and absence of cutting of fuse elements.

The above described logic information storing fuse element unit 23 stores the logic information of whether the output logic of the data stored in the above described data storing fuse element unit 21 is inverted or not (inversion “1”, non-inversion “0”) by one bit in accordance with presence and absence of cutting of the fuse elements.

The above described logic inverting unit 24A is configured by the equivalent number (10 in the drawing) of logic inversion circuits to a plurality of fuse elements of the above described data storing fuse element unit 21, inverts the output logic of all the bit data configuring the data stored in the data storing fuse element unit 21 in a bit unit, and outputs them in parallel.

The above described data selecting unit 25A is configured by the equivalent number (10 in the drawing) of data selection circuits to a plurality of fuse elements of the above described data storing fuse element unit 21, selects any one of the data with the output logic of the all the bit data configuring the data stored in the data storing fuse element unit 21 unchanged, and the data with the output logic of the all the bit data configuring the data stored in the data storing fuse element unit 21 inverted in the logic inverting unit 24A, in accordance with the logic information of one bit (“1” or “0”) of the logic information storing fuse element unit 23, and outputs the data to the latch circuit unit 22. When the logic information is “1”, the data inverted in the logic inverting unit 24A is selected and outputted, and when the logic information is “0”, the data stored in the above described data storing fuse element unit 21 is directly selected and outputted.

The above described latch circuit unit 22 is configured by a shift register including the equivalent number (10 in the drawing) of latch circuits (flip-flops) to a plurality of data selecting circuits of the above described data selecting unit 25A, and latches the data outputted from the data selecting unit 25A by the bit unit and outputs them. While it is possible to output all the bit data configuring the correct address of a defective cell in parallel from the latch circuit unit 22, it is also possible to output them serially.

Next, a circuit operation in FIG. 3 will be described.

As described above, by fuse element cutting/non-cutting processing by the fuse cutting device, the number of fuse elements with “1” to be cut out of the ten fuse elements is stored to be a half or smaller as compared with the number of fuse elements with “0” not to be cut. Meanwhile, the logic information storing fuse element unit 23 stores the logic information indicating whether inversion processing is applied to a plurality of fuse elements in the data storing fuse element unit 21 or not (“1” or “0”) in one fuse element.

When the fuse latch circuit 14 supplies the address of a defective cell to the address decoder 16 shown in FIG. 2 in such a state, the bit data output which are obtained by inputting the bit data stored with logic inversion processing applied to the ten fuse elements of the data storing fuse element unit 21 in advance into the corresponding ten logic inversion circuits of the logic inversion unit 24A and logically inverting them, and the bit data output which are the bit data stored in the ten fuse elements of the data storing fuse element unit 21 and are not inverted are respectively inputted into the ten data selecting circuits of the data selecting unit 25A. On this occasion, when the logical information adding bit stored in the logic information storing fuse element unit 23 is “1” the data selecting unit 25A is controlled to select the inverted output from the logic inverting unit 24A. Therefore, the bit data stored in the ten fuse elements of the data storing fuse element unit 21 are inverted and outputted from the ten data selecting circuits of the data selecting unit 25A, and are respectively latched into the ten latch circuits of the latch circuit unit 22. As a result, from the latch circuit unit 22, the correct address of the defective cell is generated and outputted in parallel and outputted serially to be supplied to the address decoder 16.

On the other hand, when the logic information adding bit stored in the logic information storing fuse element unit 23 is “0”, the data selecting unit 25A selects and outputs the data from the data storing fuse element unit 21, which passes by the logic inverting unit 24A, and the data are respectively latched into the ten latch circuits of the latch circuit unit 22. As a result, from the latch circuit unit 22, the correct address data of the defective cell is outputted in parallel and serially outputted, and is supplied to the address decoder 16.

Accordingly, in the fuse latch circuit 14, the data stored in the plurality of fuse elements 21a of the data storing fuse element unit 21 is inverted and outputted only when the state of the logic information storing fuse element unit 23 is “1”, and thereby, the data can be returned to the correct address data of the defective cell.

As described above, the logic inverting unit 24A and the data selecting unit 25A are interposed between the data storing fuse element unit 21 and the latch circuit unit 22, and serial output and parallel output of the data from the latch circuit unit 22 are made possible.

Here, the respective advantages of parallel output and serial output will be described.

Concerning the parallel output, in the case of transferring the address information to the other circuits frequently requiring fuse information, that is, the address information of a defective cell, the parallel output can transfer the information at a high speed and enhances performance. On the other hand, concerning the serial output, in the case of transferring information to the other circuits requiring the fuse information only when, for example, power is turned on in a chip, the serial output may be adopted. Further, with respect to the serial output, when a plurality of parallel output lines cannot be led outside the chip on the occasion of reading the data stored in the fuse elements from the chip in the test process after manufacturing the chip, the advantage of making it possible to perform the test without increasing the circuit scale at favorable cost is brought about by adopting the configuration of leading out one serial output line outside the chip instead of a plurality of parallel output lines.

According to the second embodiment, the number of fuse elements which are cut can be made not larger than a half the number of fuse elements mounted on a chip, and the number of fuse elements which are cut in the fuse element cutting process step is reduced to make it possible to enhance the throughput and yield of the process step as in the first embodiment. In addition, the advantage of making parallel output possible in addition to the serial output of the stored data is provided.

### Third Embodiment

FIG. 4 is a circuit diagram showing a fuse latch circuit of a third embodiment of the present invention.

As shown in FIG. 4, the fuse latch circuit 14 includes data storing fuse element units 21-1, 21-2 and 21-3, latch circuit units 22-1, 22-2 and 22-3, logic information storing fuse element units 23-1, 23-2 and 23-3, logic inverting units 24B-1, 24B-2 and 24B-3, and data selecting units 25B-1, 25B-2 and 25B-3.

The above described data storing fuse element units 21-1, 21-2 and 21-3 configure a plurality (three in the drawing) of fuse sets by subdividing a plurality (15, for example) of fuse elements to have a predetermined number (five in the drawing) of each of fuse elements 21-1a, 21-2a and 21-3a, and the logic information storing fuse element units 23-1, 23-2 and 23-3 are provided at the respective fuse sets.

Each of the fuse sets corresponds to a relief unit having a defect (for example, the address information of a defective cell) one-to-one as described above, and the address information of the relief unit is usually configured by a plurality of bits.

In the present embodiment, one fuse set is configured by five fuse elements, and this corresponds to the fact that the address information of the defective cell is of five bits.

Each of the above described logic information storing fuse element units 23-1, 23-2 and 23-3 includes one fuse element, and stores the logic information of whether the output logic of the above described data each of five bits is inverted or not is stored in one bit in accordance with presence or absence of cutting of the fuse element.

Concerning the data stored in the five of each of the fuse elements 21-1a, 21-2a and 21-3a of the above described data storing fuse element units 21-1, 21-2 and 21-3, when the bit data is stored in the respective five fuse elements by fuse element cutting/non-cutting processing by the fuse cutting device, the number of “1”s and the number of “0”s are independently compared for each address of the defective cell first, and it is determined whether the number of “1”s is larger or smaller than the number of “0”s.

Accordingly, speaking of, for example, the data storing fuse element unit 21-1, the number of “1”s and the number of “0”s are compared for the data of five bits which should be stored in the five fuse elements 21-1a. When the number of “1” is larger than the number of “0”s, cutting/non-cutting processing is performed for the five fuse elements 21-1a with the data which is obtained by inverting the five-bit data, and “1” is stored in one fuse element of the logic information storing fuse element unit 23-1. When the number of “1”s is smaller than the number of “0”s, cutting/non-cutting processing is performed without inverting the five-bit data, and “0” is stored in one fuse element of the logic information storing fuse element unit 23-1. The same thing applies to the divided five-bit data of each of the fuse sets of the data storing fuse element units 21-2 and 21-3, and it is determined whether the data of each of the fuse sets is logically inverted or not by comparing the number of “1”s and the number of “0”s of each of the five-bit data independently in each of the fuse sets.

The above described logic inverting units 24B-1, 24B-2 and 24B-3 are respectively paired with the data storing fuse element units 21-1, 21-2 and 21-3, and invert the output logics of the above described data each of five bits stored in the data storing fuse element units 21-1, 21-2 and 21-3 to output them.

The above described data selecting units 25B-1, 25B-2 and 25B-3 are paired with the data storing fuse element units 21-1, 21-2 and 21-3, and select any one of the data with the output logics of the above described data each of five bits stored in the data storing fuse element units 21-1, 21-2 and 21-3, and the data with the output logics of the above described data each of five bits stored in the data storing fuse element units 21-1, 21-2, and 21-3 inverted in the logic inverting units 24B-1, 24B-2 and 24B-3, in accordance with the logic information of one bit of the logic information storing fuse element units 23-1, 23-2 and 23-3 (“1” or “0”) to output them to the latch circuit units 22-1, 22-2 and 22-3. When the logic information is “1”, the data with the output logic inverted in the logic inverting units 24B-1, 24B-2 and 24B-3 are selected and outputted.

The above described latch circuit units 22-1, 22-2 and 22-3 are paired with the data selecting units 25B-1, 25B-2 and 25B-3, and are each configured by five latch circuits (flip-flops), and 15 latch circuits are continuously connected to configure a shift register. Thereby, the latch circuit units 22-1, 22-2 and 22-3 latch the data of the same number of bits from the data selecting units 25B-1, 25B-2 and 25B-3, and can output them in parallel, and output them serially.

Next, a circuit operation in FIG. 4 will be described.

The respective fuse sets of the data storing fuse element units 21-1, 21-2 and 21-3 of the fuse latch circuit 14 are in charge of the relief units each of five bits of the address of the defective cell, and whether or not to perform logic inversion is determined for each fuse set. Therefore, when cutting/non-cutting processing of five fuse elements is performed for each of the fuse sets, the number of fuse elements which are cut is a half of five bits or smaller. Namely, whether or not to perform logic inversion is determined for the address data of five bits of the defective cell for each fuse set of the three fuse sets, and the logic information adding bit is independently added to each of the fuse sets in accordance with the result of whether or not to perform logic inversion.

Therefore, according to the third embodiment, by configuring a plurality of fuse sets by subdividing a plurality of fuse elements of the data storing fuse element units into each predetermined number of fuse elements, the logic inversion unit is reduced and the total number of fuse elements which are cut can be reduced. In other words, it is made possible to enhance the logic inversion efficiency and further reduce the actual number of fuse elements which are cut.

In the embodiment described above, the example in which the fuse elements are cut by laser beam irradiation is described, but the present invention is not limited to this, and the similar effect can be also obtained when the wiring is made thinner than the normal wiring width and is broken by passing a large electric current to that portion, and an electric fuse which cut the wiring between a drain and a source or breaks an insulating film by applying high voltage to the gate of a semiconductor switch element such as an MOS transistor is used.

In the above described embodiment, a plurality of fuse elements of the data storing fuse element unit 21 which are caused to store the address data with the smaller number of fuse elements which are cut by performing logic inversion processing (inversion or noninversion) of the address of the defective cell required when the address of the redundancy cell is determined in the semiconductor device such as a DRAM are described, but the present invention is not limited only to storage of the address information of the defective cell in such a semiconductor device, and the present invention can be applied when the data indicating the identity (may be also called trace information)of the chip itself such as when and where the chip itself was made, for example, and the data specifying the characteristics of the chip itself are stored in a plurality of fuse elements in a bit unit by cutting/non-cutting processing of fuse elements. Consequently, the fuse latch circuit according to the present invention can be used when the data is stored irrespective of the kind of data, the number of actual fuse elements which are cut on this occasion can be reduced, and throughput and yield of the fuse element cutting process step can be enhanced.

According to the embodiment of the present invention described thus far, the number of actual fuse elements which are cut can be reduced, and throughput and yield of the fuse element cutting process step can be enhanced.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A fuse latch circuit, comprising:
a data storing fuse element unit configured to include a plurality of fuse elements, and store data in the respective fuse elements in a bit unit in accordance with presence and absence of cutting of the plurality of fuse elements;
a latch circuit unit configured to include an equivalent number of latch circuits to the plurality of fuse elements of the data storing fuse element unit, and latch the data stored in the data storing fuse element unit in a bit unit;
a logic information storing fuse element unit configured to store logic information of whether output logic of data stored in the fuse element is to be inverted or not in accordance with presence and absence of cutting of a fuse element;
a logic inverting unit configured to input therein the data latched in a bit unit into the plurality of the latch circuits configuring the latch circuit unit, and invert output logic of the data to output the data serially; and
a data selecting unit configured to select any one of data that is serially outputted with the output logic of the data latched in the latch circuit unit unchanged, and data that is serially outputted with the output logic of the data latched in the latch circuit unit inverted in the logic inverting unit, in accordance with logic information stored in the logic information storing fuse element unit to output the data serially.

2. A fuse latch circuit, comprising:
a data storing fuse element unit configured to include a plurality of fuse elements, and store data in the respective fuse elements in a bit unit in accordance with presence and absence of cutting of the plurality of fuse elements;
a logic information storing fuse element unit configured to store logic information of whether output logic of data stored in the fuse element is to be inverted or not in accordance with presence and absence of cutting of a fuse element;
a logic inverting unit configured to include an equivalent number of logic inverting circuits to the plurality of fuse elements configuring the data storing fuse element unit, and invert output logic of the data stored in the data storing fuse element unit in a bit unit to output the data in parallel; and
a data selecting unit configured to include an equivalent number of data selecting circuits to the plurality of fuse elements of the data storing fuse element unit, and select any one of data that is outputted in parallel, with the output logic of the data stored in the data storing fuse element unit unchanged, and data that is outputted in parallel, with the output logic of the data stored in the data storing fuse element unit inverted in the logic inverting unit, in accordance with logic information stored in the logic information storing fuse element unit to output the data in parallel; and
a latch circuit unit configured to include an equivalent number of latch circuits to the plurality of data selecting circuits configuring the data selecting unit, and latch data outputted from the data selecting unit in a bit unit to output the data in parallel and/or serially.

3. The fuse latch circuit according to claim 1,
wherein a plurality of fuse sets are configured by subdividing a plurality of fuse elements configuring the data storing fuse element unit into every predetermined number of fuse elements, and the logic information storing fuse element unit is provided for each of the fuse sets.

4. The fuse latch circuit according to claim 2,
wherein a plurality of fuse sets are configured by subdividing a plurality of fuse elements configuring the data storing fuse element unit into every predetermined number of fuse elements, and the logic information storing fuse element unit is provided for each of the fuse sets.

5. The fuse latch circuit according to claim 1,
wherein an electric fuse is used as a fuse element of the data storing fuse element unit and the logic information storing fuse element unit.

6. The fuse latch circuit according to claim 2,
wherein an electric fuse is used as a fuse element of the data storing fuse element unit and the logic information storing fuse element unit.

7. The fuse latch circuit according to claim 3,
wherein an electric fuse is used as a fuse element of the data storing fuse element unit and the logic information storing fuse element unit.

8. The fuse latch circuit according to claim 4,
wherein an electric fuse is used as a fuse element of the data storing fuse element unit and the logic information storing fuse element unit.

9. A semiconductor device, comprising:
the fuse latch circuit according to claim 1.

10. A semiconductor device, comprising:
the fuse latch circuit according to claim 2.

11. A semiconductor device, comprising:
the fuse latch circuit according to claim 3.

12. A semiconductor device, comprising:
the fuse latch circuit according to claim 4.

13. A semiconductor device, comprising:
the fuse latch circuit according to claim 5.

14. A semiconductor device, comprising:
the fuse latch circuit according to claim 6.

15. A semiconductor device, comprising:
the fuse latch circuit according to claim 7.

16. A semiconductor device, comprising:
the fuse latch circuit according to claim 8.

17. The fuse latch circuit according to claim 1,
wherein a number of the fuse elements which are cut in the data storing fuse element unit is made not larger than a half of the number of all the fuse elements of the data storing fuse element unit.

18. The fuse latch circuit according to claim 2,
wherein a number of the fuse elements which are cut in the data storing fuse element unit is made not larger than a half of the number of all the fuse elements of the data storing fuse element unit.

19. The fuse latch circuit according to claim 3,
wherein a number of the fuse elements which are cut in the data storing fuse element unit for each fuse set of the plurality of fuse sets is made not larger than a half of the number of all the fuse elements of each fuse set.

20. A semiconductor memory system, comprising:
a fuse latch circuit comprising a data storing fuse element unit configured to include a plurality of fuse elements, and store data in the respective fuse elements in a bit unit in accordance with presence and absence of cutting of the plurality of fuse elements, a latch circuit unit configured to include an equivalent number of latch circuits to the plurality of fuse elements of the data storing fuse element unit, and latch the data stored in the data storing fuse element unit in a bit unit, a logic information storing fuse element unit configured to store logic information of whether output logic of data stored in the fuse element is to be inverted or not in accordance with presence and absence of cutting of a fuse element, a logic inverting unit configured to input therein the data latched in a bit unit into the plurality of latch circuits configuring the latch circuit unit, and invert output logic of the data to output the data serially, and a data selecting unit configured to select any one of data that is serially outputted with the output logic of the data latched in the latch circuit unit unchanged, and data that is serially outputted with the output logic of the data latched in the latch circuit unit inverted in the logic inverting unit, in accordance with logic information stored in the logic information storing fuse element unit, and serially output the data, wherein the data storing fuse element unit stores data of an address of a defective cell of a cell array of a memory chip as a semiconductor device in a bit unit; and
a fuse cutting device configured to carry out the cutting of fuse elements in the fuse latch circuit, the fuse cutting device configured to invert all bit data of the address, generate “1” as a logic information adding bit of the logic information storing fuse element unit, and perform cutting/non-cutting processing of the plurality of fuse elements of the data storing fuse element unit and the fuse element of the logic information storing fuse element unit (cut in the case of “1”, non-cut in the case of “0”) when a number of “1”s is larger as compared with a number of “0”s in all the bit data configuring the address of a defective cell obtained as a result of a test of the memory chip by a memory tester, the fuse cutting device configured to leave all the bit data of the address unchanged (non-inversion), generate “0” as the logic information adding bit of the logic information storing fuse element unit, and perform cutting/non-cutting processing of the plurality of fuse elements of the data storing fuse element unit and the fuse element of the logic information storing fuse element unit when the number of“1”s is smaller as compared with the number of “0”s in all the bit data configuring the address of the defective cell, and the fuse cutting device configured not to invert all the bit data of the address stored in the data storing fuse element unit, generate “0” as the logic information adding bit of the logic information storing fuse element unit, and perform cutting/non-cutting processing of the plurality of fuse elements of the data storing fuse element unit and the fuse element of the logic information storing fuse element unit when the number of“1”s and the number of “0”s are the same in all the bit data configuring the address of the defective cell.
